(19) United States
(12) Patent Application Publication
(10) Pub. No.: US 2025/0140310 A1
(43) Pub. Date: May 1, 2025

(54) Dual Wordline Applications in Memory

(71) Applicant: Arm Limited, Cambridge (GB)

(72) Inventors: Vivek Asthana, Greater Noida (IN); Andy Wangkun Chen, Austin, TX (US); Ettore Amirante, Nice (FR); Yew Keong Chong, Austin, TX (US); Sriram Thyagarajan, Austin, TX (US)

(21) Appl. No.: 18/495,834

(22) Filed: Oct. 27, 2023

(51) Int. Cl. G11C 11/412

(52) U.S. Cl. CPC G11C 11/412

(57) ABSTRACT

Various implementations described herein are directed to a device having an array of bitcells with a first bitcell disposed adjacent to a second bitcell. The device may have a first wordline coupled to first transistors in the first bitcell, and the device may have a second wordline coupled to second transistors in the second bitcell. Also, the device may have a buried ground line coupled to the first transistors and the second transistors.

### BACKGROUND

This section is intended to provide information relevant to understanding the various technologies described herein. As the section's title implies, this is a discussion of related art that should in no way imply that it is prior art. Generally, related art may or may not be considered prior art. It should therefore be understood that any statement in this section should be read in this light, and not as any admission of prior art.

In some modern circuit architectures, deficiencies can arise when implementing multiple wordline schemes and techniques to improve speed and performance in common memory applications. For instance, multiple metal layers can be used to provide multiple different wordlines along with multiple power rails; however, this memory design increases area and slows performance due to multiple additional layers formed on a substate. Also, any additional metal layers added frontside typically reduces memory speed due to added capacitance from additional conductive layers formed to overlie each other. Thus, there exists a need for a more efficient bitcell design that seeks to reduce area inefficiencies, improve integration schemes, and enhance speed and performance by providing more effective wordline design schemes and techniques for memory based applications.

### BRIEF DESCRIPTION OF THE DRAWINGS

Implementations of various techniques are described herein with reference to the accompanying drawings. It should be understood, however, that the accompanying drawings illustrate only various implementations described herein and are not meant to limit embodiments of various techniques described herein.

FIGS. 1A-1C illustrate various schematic diagrams of bitcell array architecture in a first configuration in accordance with implementations described herein.

FIGS. 2A-2C illustrate various schematic diagrams of bitcell array architecture in a second configuration in accordance with implementations described herein.

FIG. 3 illustrates a diagram of bitcell array architecture in a third configuration in accordance with various implementations described herein.

### DETAILED DESCRIPTION

Various implementations described herein refer to dual wordline schemes and techniques for single-port memory applications in various circuit related designs. Also, in some implementations, dual wordline schemes and techniques described herein provide for bank-selective and/or bit-selective optimized timing designs that utilize buried backside wordlines, frontside wordlines and/or various combinations thereof. Therefore, in various applications, the dual wordline schemes and techniques described herein may provide for various combinations of frontside and buried backside conductive lines, such as, e.g., frontside/buried wordlines, frontside/buried power rail-lines, etc., that may optimize and/or improve area, speed and performance of memory in some memory based applications, such as, e.g., static random access memory (SRAM), and/or similar.

In some implementations, the dual wordline schemes and techniques described herein provide a single-port memory design using multiple wordlines (e.g., 2) and a buried ground line (VSS) that may be used to reduce dynamic power and improve wordline RC delay (i.e., wordline resistor-capacitor delay). In some applications, the buried ground line (VSS) is formed in buried backside metal using buried metal technology, which enables the multiple wordlines (e.g., 2) in frontside metal, and which allows for a single-port column multiplexer design having low power and high speed.

In some implementations, the dual wordline schemes and techniques described herein provide a single-port memory design using multiple wordlines (e.g., 2), including, e.g., one frontside wordline and one buried backside wordline. In some applications, this frontside-backside wordline technique provides an improved memory design with faster timing for a portion (e.g., half) of the address space so as to improve overall system-on-a-chip (SoC) timing. Also, in some applications, the buried wordline may be added to the backside layer using buried metal technology. As such, with this different memory design, multiple memory instances (e.g., 2) may be merged into a single memory instance.

In some implementations, the dual wordline schemes and techniques described herein provide a single-port memory design with faster timing for a few selected bits in a memory bank. In some applications, another wordline may be added to a backside layer using buried metal technology to improve timing for a few selected bits. Also, this idea may be used in processor designs, where a few bits are more timing critical to meet various micro-architecture constraints, behaviors and/or characteristics.

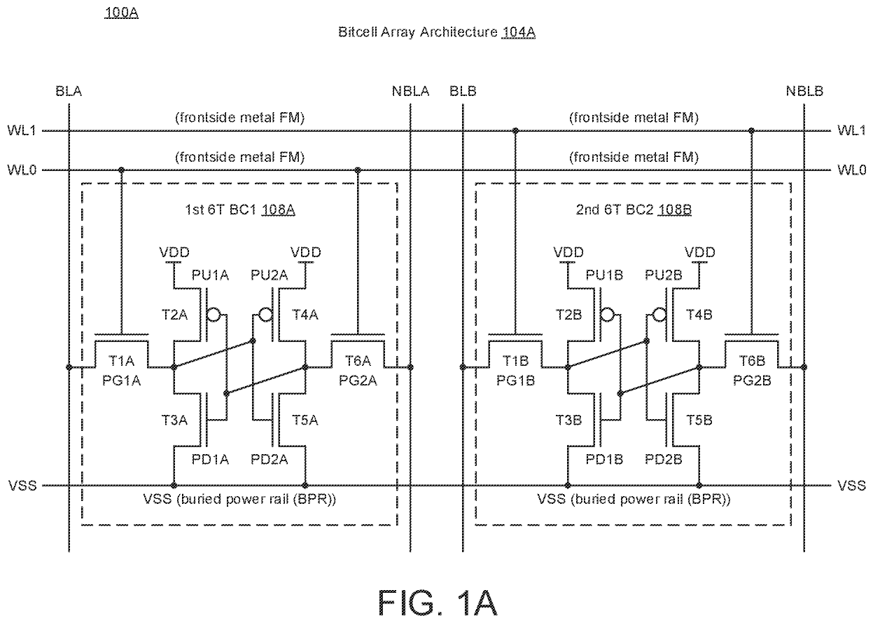

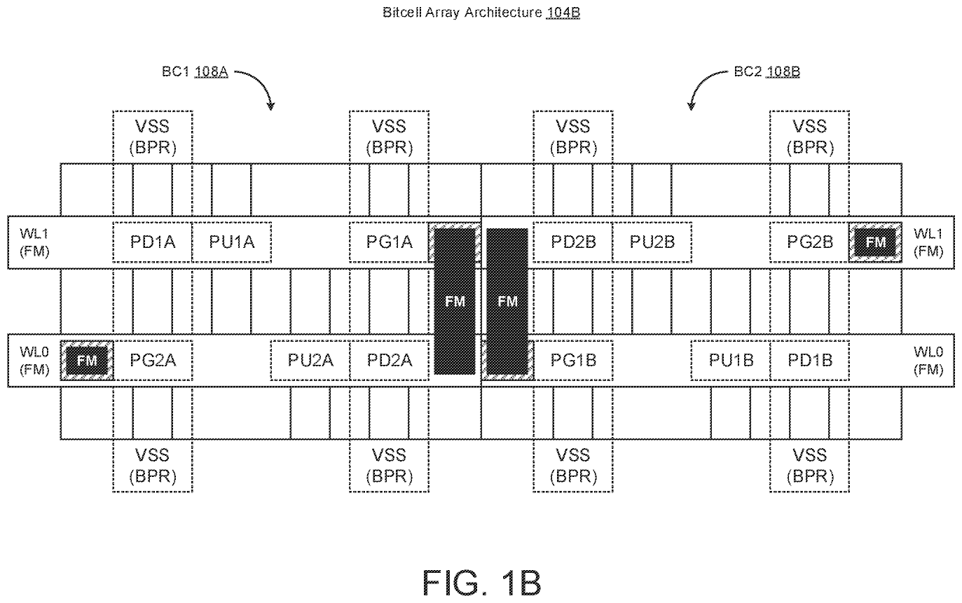

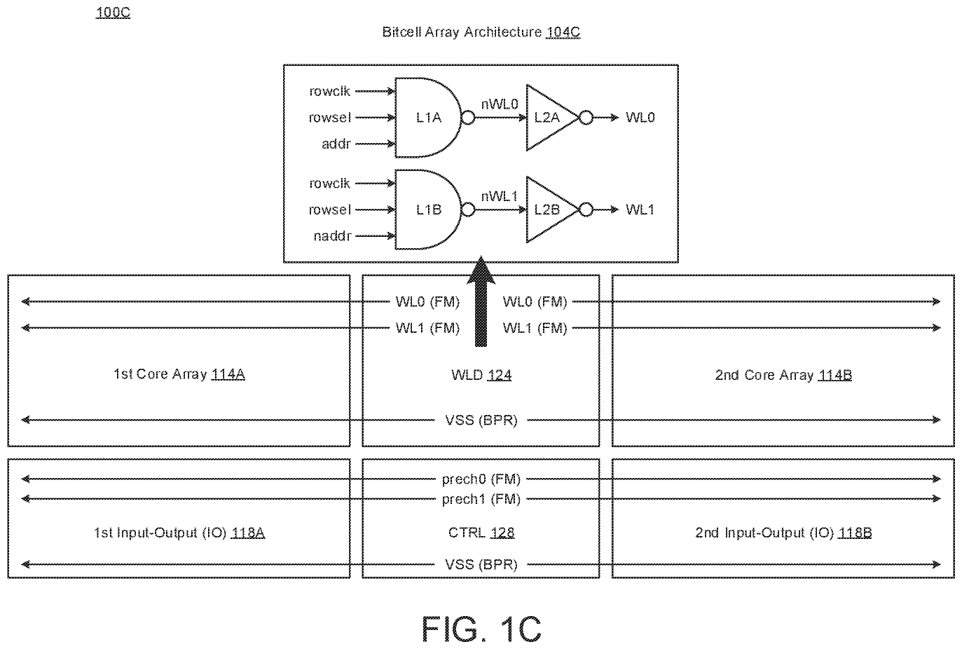

Various implementations of multi-transistor bitcell schemes and techniques for memory based applications will now be described herein in FIGS. 1A-1B to 4A-4B.

FIGS. 1A-1C illustrate various diagrams of bitcell array architecture in a first configuration in accordance with various implementations described herein. In particular, FIG. 1A shows a schematic diagram 100A of bitcell array architecture 104A in the first configuration, FIG. 1B shows a top-view diagram 100B of bitcell array architecture 104B in the first configuration, and also, FIG. 1C shows a core array diagram 100C of bitcell array architecture 104C in the first configuration.

In various implementations, bitcell architecture 104A, 104B, 104C may provide for fabricating memory circuitry with various integrated circuit (IC) components that may be arranged and/or coupled together as an assemblage or some combination of parts that provide for physical circuit designs, structures and/or applications. In some instances, a method of designing, providing and fabricating the bitcell architectures 104A, 104B, 104C as an integrated device may involve use of circuit components and/or related structures described herein so as to implement various techniques associated therewith. Also, the bitcell architectures 104A, 104B, 104C may be integrated with various circuitry and related components on a single chip, and further, the bitcell architectures 104A, 104B, 104C may be implemented in various embedded devices for automotive, mobile, computer, server and/or Internet-of-Things (IoT) based applications, including remote sensor nodes.

As shown in FIG. 1A, the bitcell architecture 104A may be implemented as a device having an array of bitcells (BC) 108A, 108B including, e.g., a first bitcell 108A that is disposed adjacent to (next to) a second bitcell 108B. Also, the bitcell architecture 104A may include a first wordline (WL0) coupled to first transistors (T1A, T6A) in the first bitcell 108A, a second wordline (WL1) coupled to second transistors (T1B, T6B) in the second bitcell (108B), and one or more buried power rails (BPR), such as, e.g., a buried ground rail or line (VSS). As such, in some instances, the one or more buried power rails or lines, such as, e.g., buried ground rail or line (VSS), may be coupled to one or more transistors in the first bitcell 108A and/or the second bitcell 108B, such as, e.g., the first transistors (T1A, T6A) and/or the second transistors (T1B, T6B).

In various implementations, the first wordline (WL0) and/or the second wordline (WL1) may be formed in a frontside metal layer (FM) that is disposed above the buried ground rail or line (VSS-BPR), and also, the buried ground line (VSS-BPR) may be formed in a buried backside metal layer (BM) that is disposed below the first wordline (WL0) and the second wordline (WL1). Also, the first bitcell 108A may be a first multi-transistor bitcell with the first transistors (T1A, T6A) coupled to first complementary bitlines (BLA, NBLA) as first passgates (PG1A, PG2A), wherein the first wordline (WL0) is coupled to gates of the first passgates (PG1A, PG2A). Also, the second bitcell 108B may be a second multi-transistor bitcell with the second transistors (T1B, T6B) coupled to second complementary bitlines (BLB, NBLB) as second passgates (PG1B, PG2B), wherein the second wordline (WL1) is coupled to gates of the second passgates (PG1B, PG2B).

In various implementations, the frontside metal layer (FM) may refer to and may be disposed as any frontside metal layer, such as, e.g., a metal-zero (M0) layer, a metal-one (M1) layer, etc. In some memory applications, such as, e.g., in static random access memory (SRAM) applications, bitlines (BL) may be formed and/or disposed in a frontside metal-zero (M0) layer, and wordlines (WL) may be formed and/or disposed in a metal-one (M0) layer. Also, in various implementations, the buried backside metal layer (BM) may refer to and may be disposed as any buried backside metal layer, such as, e.g., a buried metal-zero (B0) layer, a buried metal-one (B1) layer, etc. In some memory applications, such as, e.g., as described herein in SRAM applications, wordlines (WL) may be formed and/or disposed in a buried backside metal-zero (B0) layer. Also, power rail-lines, such as, e.g., a voltage supply rail-line (VDD) and a ground rail-line (VSS) may be formed as and/or disposed in a buried backside metal layer (BM), such as, e.g., a B0 layer, wherein the buried ground rail-line (VSS-BPR) may be formed in a buried B0 layer. Also, in some applications, the power rail-lines, such as, e.g., the voltage supply rail-line (VDD) and the ground rail-line (VSS) may be formed as and/or disposed in a frontside metal layer (FM), such as, e.g., a M0 layer, wherein the frontside ground rail-line (VSS-FPR) may be formed and/or disposed in a frontside M0 layer.

In various implementations, the array of bitcells, including, e.g., the first bitcell 108A and the second bitcell 108B, may be static random access memory (SRAM) bitcells for single-port memory applications. As shown in FIG. 1A, each bitcell (BC) 108A, 108B may include a plurality of transistors (e.g., T1, T2, . . . , T6) that are arranged and coupled together to operate as a multi-transistor bitcell structure, such as, e.g., a 6-transistor (6T) bitcell structure for various memory based applications. In some instances, the first bitcell 108A may include transistors (T2A, T3A, T4A, T5A) arranged as cross-coupled inverters (T2A/T3A and T4A/T5A) that are coupled between a voltage supply (VDD) and the buried ground rail or line (VSS-BPR). Also, the first bitcell 108A may have transistors (T1A, T6A) arranged and/or coupled as the first passgates (PG1A, PG2A) between the cross-coupled inverters (T2A/T3A and T4A/T5A) and the complementary bitlines (BLA, NBLA). Further, the second bitcell 108B may include transistors (T2B, T3B, T4B, T5B) arranged as cross-coupled inverters (T2B/T3B and T4B/T5B) that are coupled between the voltage supply (VDD) and the buried ground rail or line (VSS-BPR). In addition, the second bitcell 108B may also have transistors (T1B, T6B) arranged and/or coupled as the second passgates (PG1B, PG2B) between the cross-coupled inverters (T2B/T3B and T4B/T5B) and the complementary bitlines (BLB, NBLB).

As shown in FIG. 1A, the bitcell architecture 104A may be implemented with one or more multi-transistor bitcell structures, such as, e.g., one or more 6T bitcell related structures 108A, 108B. In various implementations, each multi-transistor bitcell structure 108A, 108B may be configured as a multi-transistor (e.g., six-transistor (6T)) single-port SRAM bitcell structure, wherein the six transistors (6T) may have multiple (e.g., 4)N-type metal-oxide-semiconductor (NMOS) transistors along with multiple (e.g., 2) P-type MOS (PMOS) transistors. For instance, in some implementations, the transistors (T1A, T2A, . . . , T6A and T1B, T2B, . . . , T6B) may comprise P-type transistors and N-type transistors that are formed with P-type and N-type complementary field effect transistor (PN CFET) technology. Also, transistors (T2A, T4A and T2B, T4B) may be P-type transistors, and transistors (T1A, T3A, T5A, T6A and T1B, T3B, T5B, T6B) may be N-type transistors.

Also, in various implementations, transistors (T2A, T3A and T2B, T3B) may be coupled in series between voltage supply (VDD) and the buried ground rail or line (VSS-BPR), wherein transistors (T2A, T2B) may refer to pull-up transistors (PU1A, PU1B), and wherein transistors (T3A, T3B) may refer to pull-down transistors (PD1A, PD1B). Also, transistors (T4A, T5A and T4B, T5B) may be coupled in series between the voltage supply (VDD) and the buried ground rail or line (VSS-BPR), wherein transistors (T4A, T4B) may refer to pull-up transistors (PU2A, PU2B), and wherein transistors (T5A, T5B) may refer to pull-down transistors (PD2A, PD2B).

In various implementations, one or more conductive lines may be buried within a substrate, e.g., in a buried backside metal layer. For instance, in some applications, the transistors (T1A, T2A, . . . , T6A and T1B, T2B, . . . , T6B) may be formed on a substrate, and optionally, in various instances, the voltage supply (VDD) and/or the ground line (VSS or GND) may be buried in the substate as a buried power line (BPR). For instance, as shown in FIG. 1A, the ground line (VSS or GND) may be buried within the substate as a buried ground rail or line (VSS-BPR). Also, optionally, in various instances, one or more wordlines (WL0, WL1) may comprise a buried wordline formed within the substrate. Also, optionally, in various applications, one or more bitlines (BLA/NBLA and BLB, NBLB) may comprise buried bitlines formed within the substrate.

As shown in FIG. 1B, the bitcell array architecture 104B is represented as a top-view of the bitcell array layout showing the wordlines (WL0, WL1) formed in frontside metal (FM) coupled to transistors in adjacent bitcells 108A, 108B. For instance, the array of bitcells include the first bitcell 108A disposed adjacent to the second bitcell 108B, such that the first wordline (WL0) is coupled to the first transistors (T1A, T6A) in the first bitcell (BC1) 108A, and such that the second wordline (WL1) is coupled to the second transistors in the second bitcell (BC2) 108B. Also, the buried ground rail or line (VSS-BPR) is coupled to gates of the first transistors (T1A, T6A) and the second transistors (T1B, T6B).

As shown in FIG. 1C, the bitcell array architecture 104C may include multiple core arrays, including, e.g., a first core array 114A and a second core array 114B, coupled to wordline driver circuitry (WLD) 124. Also, the bitcell array architecture 104C may have control circuitry (CTRL) 128 coupled to multiple input-output (IO) circuits, including, e.g., a first IO circuit 118A and a second IO circuit 118B.

In some implementations, the wordline driver circuitry (WLD) 124 is configured to provide wordline signals to the bitcells (BCs) in the first core array 114A and the second core array 114B by way of the first wordline (WL0) and the second wordline (WL1), e.g., in a manner as shown in FIG. 1A. As described herein, the wordlines (WL0, WL1) may be formed as frontside conductive rails or lines in frontside metal (FM) layers. Also, the bitcell array architecture 104C may include the buried ground rail or line (VSS-BPR) that is coupled to the bitcells (BCs) in the first core array 114A and the second core array 114B, in a manner as shown in FIG. 1A.

In some implementations, the wordline driver circuitry (WLD) 124 may include various logic gates (e.g., L1A, L1B, L2A, L2B) that are arranged and coupled together to receive input signals (e.g., rowclk, rowsel, addr, naddr) and provide the wordline signals (WL0, WL1) to the first core array 114A and the second core array 114B by way of the first wordline (WL0) and the second wordline (WL1). For instance, logic gate (L1A) may be coupled in series with logic gate (L2A), wherein logic gate (L1A) receives a row clock signal (rowclk), receives a row select signal (rowsel), receives an address signal (addr), and then provides a first inverted wordline signal (nWL0) to logic gate (L2A) that inverts the nWL0 signal to provide the first wordline signal (WL0). Also, logic gate (L1B) may be coupled in series with logic gate (L2B), wherein logic gate (L1B) receives the row clock signal (rowclk), receives the row select signal (rowsel), receives complementary address signal (naddr), and provides a second inverted wordline signal (nWL1) to logic gate (L2B) that then inverts the nWL0 signal to provide the second wordline (WL1) signal. In some instances, logic gates (L1A, L1B) may be NAND gates, and logic gates (L2A, L2B) may be inverters. However, various other logic gate configurations may be used to achieve similar results, behaviors and/or characteristics.

In some implementations, the control circuitry (CTRL) 128 may include one or more precharge lines (prech0, prech1) that are coupled to the first complementary bitlines (BLA, NBLA) and the second complementary bitlines (BLB, NBLB) of FIG. 1A. Also, in some applications, the control circuitry (CTRL) 128 may use the precharge lines (prech0, prech1) to precharge at least one of the first complementary bitlines (BLA, NBLA) and the second complementary bitlines (BLB, NBLB). Also, in some applications, the precharge lines (prech0, prech1) may be formed as frontside conductive rails or lines in the frontside metal (FM) layers. Also, the control circuitry (CTRL) 128 may include the buried ground rail or line (VSS-BPR) that is coupled to the bitcells (BCs) in the first core array 114A and the second core array 114B, in a manner as shown in FIG. 1A.

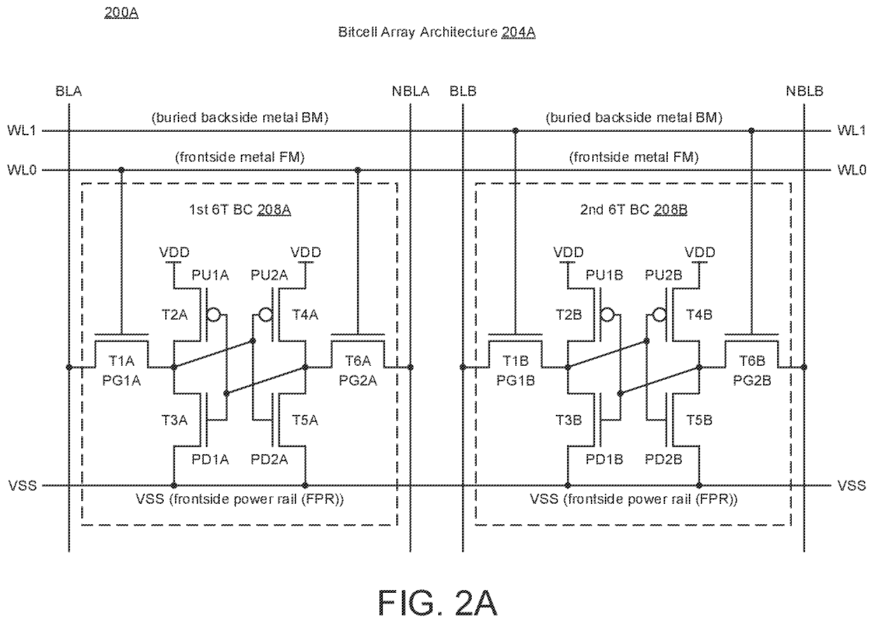

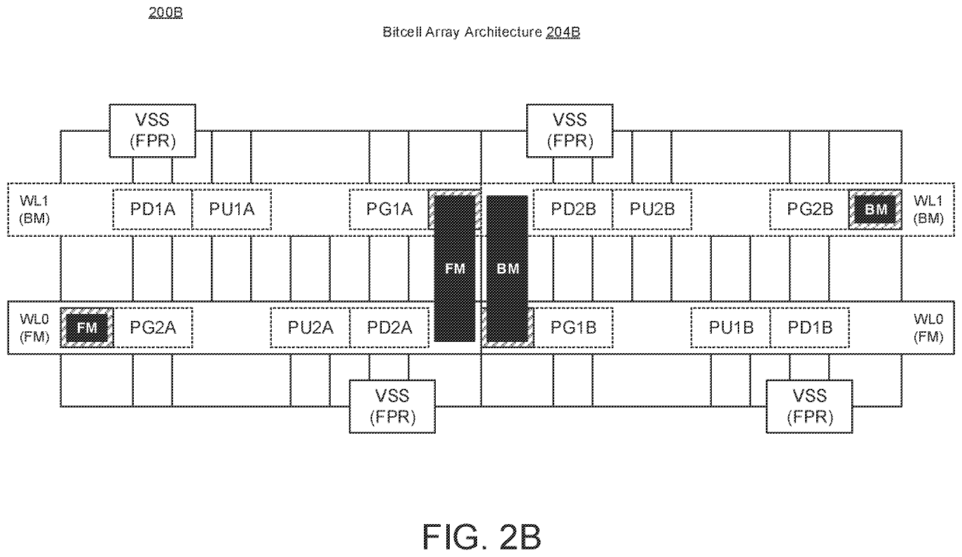

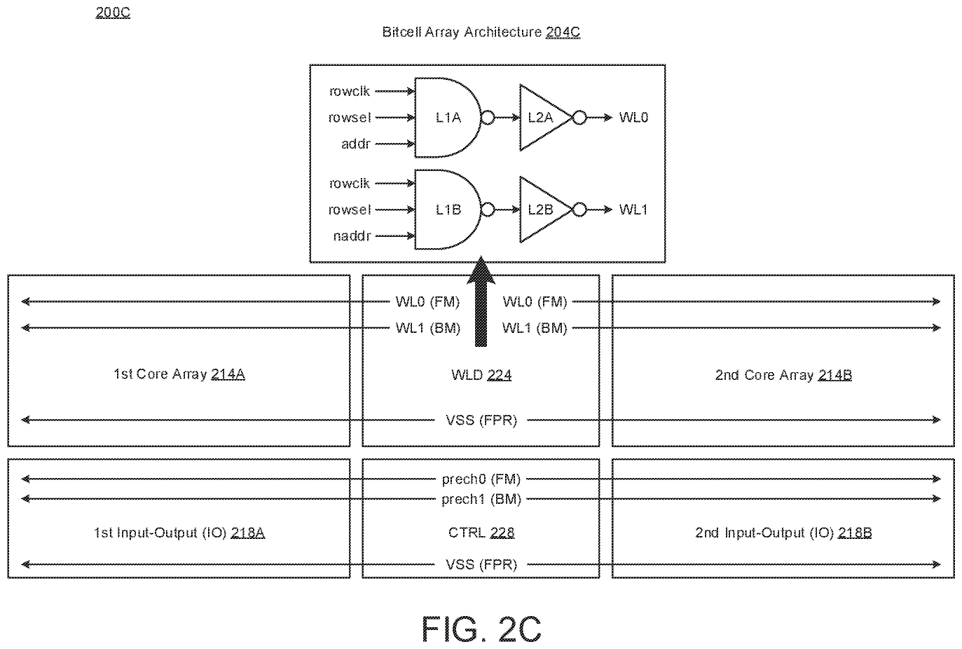

FIGS. 2A-2C show various diagrams of bitcell array architecture in a second configuration in accordance with various implementations described herein. In particular, FIG. 2A shows a schematic diagram 200A of bitcell array architecture 204A in a second configuration, FIG. 2B shows a top-view diagram 200B of bitcell array architecture 204B in the second configuration, and also, FIG. 2C shows another core array diagram 200C of bitcell array architecture 204C in the second configuration.

In various implementations, bitcell architecture 204A, 204B, 204C may provide for fabricating memory circuitry with various integrated circuit (IC) components that may be arranged and/or coupled together as an assemblage or some combination of parts that provide for physical circuit designs, structures and/or applications. In some instances, a method of designing, providing and fabricating the bitcell architectures 204A, 204B, 204C as an integrated device may involve use of circuit components and/or related structures described herein so as to implement various techniques associated therewith. Also, the bitcell architectures 204A, 204B, 204C may be integrated with various circuitry and related components on a single chip, and further, the bitcell architectures 204A, 204B, 204C may be implemented in various embedded devices for automotive, mobile, computer, server and/or Internet-of-Things (IoT) based applications, including remote sensor nodes.

As shown in FIG. 2A, the bitcell architecture 204A may be implemented as a device having an array of bitcells (BC) 208A, 208B including, e.g., a first bitcell 208A that is disposed adjacent to (next to) a second bitcell 208B. Also, the bitcell architecture 204A may include a frontside wordline (WL0) coupled to first transistors (T1A, T6A) in the first bitcell 208A, a buried backside wordline (WL1) coupled to second transistors (T1B, T6B) in the second bitcell (208B), and one or more frontside power rails (FPR), such as, e.g., a frontside ground rail or line (VSS). As such, in some instances, the one or more frontside power rails or lines, such as, e.g., frontside ground rail or line (VSS), may be coupled to one or more transistors in the first bitcell 208A and/or the second bitcell 208B, such as, e.g., the first transistors (T1A, T6A) and/or the second transistors (T1B, T6B).

In some implementations, the frontside wordline (WL0) and the frontside ground rail-line (VSS-FPR) may be formed in a frontside metal layer (FM) that is disposed above the buried backside wordline (WL1). Also, the buried backside wordline (WL1) may be formed in a buried backside metal layer (BM) that is disposed below the frontside wordline (WL0) and the frontside ground rail-line (VSS-FPR). Also, the first bitcell 208A may be a first multi-transistor bitcell with first transistors (T1A, T6A) coupled to first complementary bitlines (BLA, NBLA) as first passgates (PG1A, PG2A), wherein the frontside wordline (WL0) is coupled to gates of the first passgates (PG1A, PG2A). Also, the second bitcell 208B may be a second multi-transistor bitcell with second transistors (T1B, T6B) coupled to second complementary bitlines (BLB, NBLB) as second passgates (PG1B, PG2B), wherein the buried backside wordline (WL1) is coupled to gates of the second passgates (PG1B, PG2B), in some applications.

In various implementations, the array of bitcells, including, e.g., the first bitcell 208A and the second bitcell 208B, may be static random access memory (SRAM) bitcells for single-port memory applications. As shown in FIG. 2A, each bitcell (BC) 208A, 208B may include a plurality of transistors (e.g., T1, T2, . . . , T6) that are arranged and coupled together to operate as a multi-transistor bitcell structure, such as, e.g., a 6-transistor (6T) bitcell structure for various memory based applications. In some instances, the first bitcell 208A may include transistors (T2A, T3A, T4A, T5A) arranged as cross-coupled inverters (T2A/T3A and T4A/T5A) that are coupled between voltage supply (VDD) and the frontside ground rail or line (VSS-FPR). Also, the first bitcell 208A may have transistors (T1A, T6A) arranged and/or coupled as the first passgates (PG1A, PG2A) between the cross-coupled inverters (T2A/T3A and T4A/T5A) and the complementary bitlines (BLA, NBLA). Further, the second bitcell 208B may include transistors (T2B, T3B, T4B, T5B) arranged as cross-coupled inverters (T2B/T3B and T4B/T5B) that are coupled between the voltage supply (VDD) and the frontside ground rail or line (VSS-FPR). Also, the second bitcell 208B may include transistors (T1B, T6B) arranged and/or coupled as the second passgates (PG1B, PG2B) between the cross-coupled inverters (T2B/T3B and T4B/T5B) and complementary bitlines (BLB, NBLB), in some applications.

As shown in FIG. 2A, the bitcell architecture 204A may be implemented with one or more multi-transistor bitcell structures, such as, e.g., one or more 6T bitcell related structures 208A, 208B. In various implementations, each multi-transistor bitcell structure 208A, 208B may be configured as a multi-transistor (e.g., six-transistor (6T)) single-port SRAM bitcell structure, wherein the six transistors (6T) may have multiple (e.g., 4)N-type metal-oxide-semiconductor (NMOS) transistors along with multiple (e.g., 2) P-type MOS (PMOS) transistors. For instance, in some implementations, the transistors (T1A, T2A, . . . , T6A and T1B, T2B, . . . , T6B) may comprise P-type transistors and N-type transistors that are formed with P-type and N-type complementary field effect transistor (PN CFET) technology. Also, transistors (T2A, T4A and T2B, T4B) may be P-type transistors, and transistors (T1A, T3A, T5A, T6A and T1B, T3B, T5B, T6B) may be N-type transistors.

Also, in various implementations, transistors (T2A, T3A and T2B, T3B) may be coupled in series between voltage supply (VDD) and the frontside ground rail or line (VSS-FPR), wherein transistors (T2A, T2B) may refer to pull-up transistors (PU1A, PU1B), and wherein transistors (T3A, T3B) may refer to pull-down transistors (PD1A, PD1B). Also, transistors (T4A, T5A and T4B, T5B) may be coupled in series between the voltage supply (VDD) and the frontside ground rail or line (VSS-FPR), wherein transistors (T4A, T4B) may refer to pull-up transistors (PU2A, PU2B), and wherein transistors (T5A, T5B) may refer to pull-down transistors (PD2A, PD2B).

In various implementations, one or more conductive lines may be buried within a substrate, e.g., in a buried backside metal layer. For instance, in some applications, the transistors (T1A, T2A, . . . , T6A and T1B, T2B, . . . , T6B) may be formed on a substrate, and optionally, in various instances, the voltage supply (VDD) and/or the ground line (VSS or GND) may be formed above the substate as a frontside power rail or line (FPR) or may be formed below the substate as buried backside rail or line (BPR). In various instances, as shown in FIG. 2A, the ground line (VSS or GND) may be formed above the substate as a frontside ground rail-line (VSS-FPR). Also, optionally, in various instances, one or more wordlines (WL0, WL1) may formed as a buried wordline that may be formed within the substrate. Also, optionally, in some applications, one or more bitlines (BLA/NBLA and BLB, NBLB) may comprise buried bitlines formed within the substrate.

As shown in FIG. 2B, the bitcell array architecture 204B is represented as a top-view of the bitcell array layout showing wordline (WL0) formed in frontside metal (FM) and wordline (WL1) formed in buried backside metal (BM), wherein the wordlines (WL0, WL1) are also coupled to corresponding transistors in adjacent bitcells 208A, 208B. For instance, the array of bitcells include the first bitcell 208A disposed adjacent to the second bitcell 208B, such that the frontside wordline (WL0) is coupled to the first transistors (T1A, T6A) in the first bitcell (BC1) 208A, and such that the buried backside wordline (WL1) is coupled to the second transistors in the second bitcell (BC2) 208B. Further, the frontside ground rail or line (VSS-FPR) may be coupled to gates of the first transistors (T1A, T6A) and the second transistors (T1B, T6B).

As shown in FIG. 2C, the bitcell array architecture 204C may include multiple core arrays, including, e.g., a first core array 214A and a second core array 214B, coupled to wordline driver circuitry (WLD) 224. Also, the bitcell array architecture 204C may have control circuitry (CTRL) 228 coupled to multiple input-output (IO) circuits, including, e.g., a first IO circuit 218A and a second IO circuit 218B.

In some implementations, the wordline driver circuitry (WLD) 224 is configured to provide wordline signals to the bitcells (BCs) in the first core array 214A and the second core array 214B by way of the frontside wordline (WL0) and the buried backside wordline (WL1), e.g., in a manner as shown in FIG. 2A. As described herein, the wordline (WL0) may be formed as a frontside conductive rail or line (FPR) in a frontside metal (FM) layer, and the wordline (WL1) may be formed as a buried backside conductive rail-line (BPR) in a buried backside metal (BM) layer. Also, the bitcell array architecture 204C may include the frontside ground rail or line (VSS-FPR) that is coupled to the bitcells (BCs) in the first core array 214A and second core array 214B, in a manner as shown in FIG. 2A.

In some implementations, the wordline driver circuitry (WLD) 224 may include various logic gates (e.g., L1A, L1B, L2A, L2B) that are arranged and coupled together to receive input signals (e.g., rowclk, rowsel, addr, naddr) and provide the wordline signals (WL0, WL1) to the first core array 214A and the second core array 214B by way of the frontside wordline (WL0) and buried backside wordline (WL1). For instance, logic gate (L1A) may be coupled in series with logic gate (L2A), wherein logic gate (L1A) receives a row clock signal (rowclk), receives a row select signal (rowsel), receives an address signal (addr), and then provides a first inverted wordline signal (nWL0) to logic gate (L2A) that inverts the nWL0 signal to provide the frontside wordline signal (WL0). Also, logic gate (L1B) may be coupled in series with logic gate (L2B), wherein logic gate (L1B) receives the row clock signal (rowclk), receives row select signal (rowsel), receives complementary address signal (naddr), and provides a second inverted wordline signal (nWL1) to logic gate (L2B) that then inverts the nWL0 signal to provide the buried backside wordline (WL1) signal. In some instances, logic gates (L1A, L1B) may be NAND gates, and logic gates (L2A, L2B) may be inverters. However, various other logic gate configurations may be used to achieve similar results, behaviors and/or characteristics.

In some implementations, the control circuitry (CTRL) 228 may include one or more precharge lines (prech0, prech1) that are coupled to the first complementary bitlines (BLA, NBLA) and the second complementary bitlines (BLB, NBLB) of FIG. 2A. Also, in some applications, the control circuitry (CTRL) 228 may use the precharge lines (prech0, prech1) to precharge at least one of the first complementary bitlines (BLA, NBLA) and the second complementary bitlines (BLB, NBLB). Also, in some applications, the precharge lines (prech0, prech1) may have a frontside precharge line (prech0) formed as a frontside conductive rail-line in a frontside metal (FM) layer, and also, the precharge lines (prech0, prech1) may have a buried backside precharge line (prech1) formed as a buried backside conductive rail-line in a buried backside metal (BM) layer. Also, control circuitry (CTRL) 228 may include the frontside ground rail or line (VSS-FPR) that is coupled to the bitcells (BCs) in the first core array 214A and the second core array 214B, in a manner as shown in FIG. 2A, in some applications. Also, in some other applications, the frontside ground rail-line (VSS-FPR) may be formed as a buried backside ground rail-line (VSS-BPR).

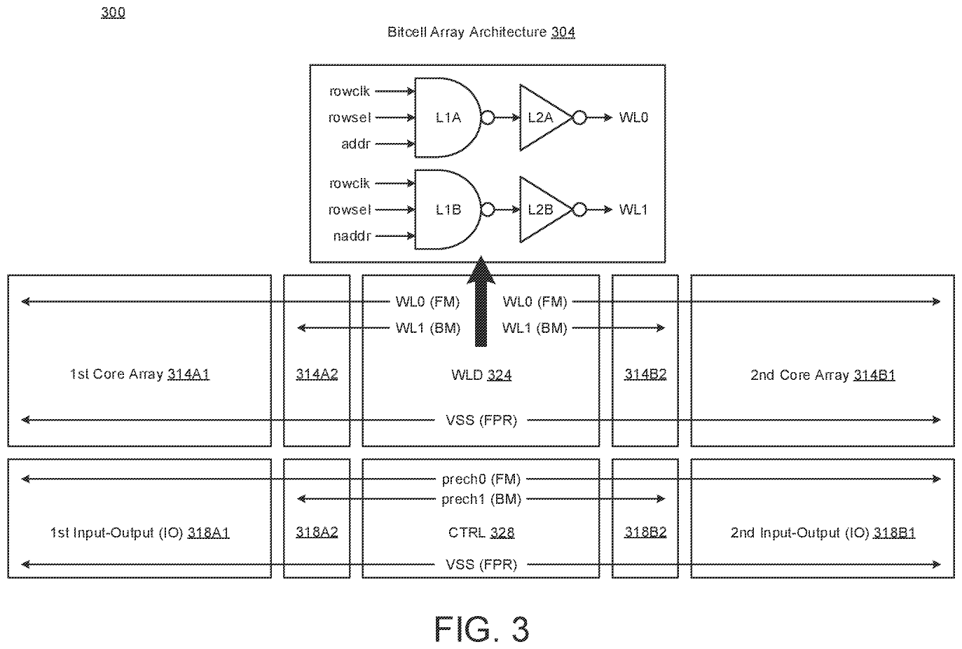

FIG. 3 illustrates a diagram of bitcell array architecture in a third configuration in accordance with various implementations described herein. Various features, aspects, and components shown in FIG. 3 may relate to similar and/or corresponding features, aspects, and components as shown in FIGS. 1C and 2C.

In various implementations, bitcell architecture 304 may provide for fabricating memory circuitry with various integrated circuit (IC) components that are arranged and/or coupled together as an assemblage or some combination of parts that provide for physical circuit designs, structures and/or applications. In some instances, a method of designing, providing and fabricating the bitcell architecture 304 as an integrated device may involve use of circuit components and/or related structures described herein so as to implement various techniques associated therewith. Also, bitcell architecture 304 may be integrated with various circuitry and related components on a single chip, and the bitcell architecture 304 may be implemented in various embedded devices for automotive, mobile, computer, server and/or IoT based applications, including remote sensor nodes.

As shown in FIG. 3, the bitcell architecture 304 may be implemented as a device having an array of bitcells with first bitcells and second bitcells, wherein the first bitcells are disposed in a first portion of the array (e.g., 314A1, 314B1), and wherein the second bitcells are disposed in a second portion of the array (e.g., 314A2, 314B2) that is different than the first portion of the array. Also, the bitcell architecture 304 may include a plurality of wordlines (WL0, WL1) including, e.g., a frontside wordline (WL0) and a buried backside wordline (WL1) formed below the frontside wordline (WL0), wherein the frontside wordline (WL0) couples a wordline driver circuit (WDL) 324 to the first bitcells in the first portion of the array (e.g., 314A1, 314B1), and wherein the buried backside wordline (WL1) couples the wordline driver circuit (WLD) 324 to the second bitcells in the second portion of the array (e.g., 314A2, 314B2). Also, in various applications, the second bitcells in the second portion of the array (e.g., 314A2, 314B2) may be disposed closer to the wordline driver circuit (WLD) 324 than the first bitcells in the first portion of the bitcell array (e.g., 314A1, 314B1). In addition, the buried backside wordline (WL1) may be shorter in length than the frontside wordline (WL0).

In some implementations, the first bitcells may include first transistors, and also, the frontside wordline (WL0) may be configured to couple the wordline driver circuit (WLD) 324 to the first transistors in the first bitcells. Also, the second bitcells may include second transistors, and also, the buried backside wordline (WL1) may be configured to couple the wordline driver circuit (WLD) 324 to the second transistors in the second bitcells. Further, the frontside wordline (WL0) may be formed in a frontside metal (FM) layer, and the buried backside wordline (WL1) may be formed beneath the frontside wordline (WL0) in a buried backside metal (BM) layer that is disposed below the frontside metal (FM) layer. Further, the first bitcells and the second bitcells are static random access memory (SRAM) bitcells for single-port memory applications.

In some implementations, the bitcell architecture 304 may include a frontside ground rail-line (VSS-FPR) coupled to the first transistors and the second transistors, and also, the frontside ground rail-line (VSS-FPR) may be formed in a frontside metal (FM) layer. However, in other applications, the ground rail-line (VSS) may be a buried backside ground rail-line (VSS-BPR) formed in a buried backside metal (BM) layer.

In some implementations, as shown in FIG. 3, the bitcell array architecture 304 may include control circuitry (CTRL) 328 coupled to multiple input-output (IO) circuits, including, e.g., first IO circuits 318A1, 318A2 and second IO circuits 318B1, 318B2. Also, first IO circuit 318A1 is coupled to the corresponding core array 314A1, and first IO circuit 318A2 is coupled to the corresponding core array 314A2. Also, second IO circuit 318B1 is coupled to the corresponding core array 314B1, and second IO circuit 318B2 is coupled to the corresponding core array 314B2.

In some implementations, the bitcell architecture 304 may include the frontside precharge line (prech0) that is configured to precharge first complementary bitlines (BLA, NBLA) coupled to first bitcells in the first portion of the array (e.g., 314A1, 314B1). Also, the bitcell architecture 304 may have the buried precharge line (prech1) that is configured to precharge second complementary bitlines (BLB, NBLB) coupled to the second bitcells in the second portion of the array (e.g., 314A2, 314B2). Also, the buried precharge line (WL1) may be shorter in length than the frontside precharge line (prech0). Also, in various applications, the control circuitry (CTRL) 328 may include the frontside ground rail-line (VSS-FPR) that is coupled to the bitcells (BCs) in the first core array 314A1, 314A2 and the second core array 314B1, 314B2. In other applications, the frontside ground rail-line (VSS-FPR) may be formed as a buried backside ground rail-line (VSS-BPR).

Reference has been made in detail to various implementations, examples of which are illustrated in the accompanying drawings and figures. In the following detailed description, numerous specific details are set forth to provide a thorough understanding of the disclosure provided herein. However, the disclosure provided herein may be practiced without these specific details. In some other instances, well-known methods, procedures, components, circuits and networks have not been described in detail so as not to unnecessarily obscure details of the embodiments.

Described herein are various implementations of a device having an array of bitcells with a first bitcell disposed adjacent to a second bitcell. The device may include a first wordline coupled to first transistors in the first bitcell, and the device may include a second wordline coupled to second transistors in the second bitcell. Also, the device may include a buried ground line coupled to the first transistors and the second transistors.

Described herein are various implementations of a device having an array of bitcells having a first bitcell disposed adjacent to a second bitcell. The device may have a frontside wordline coupled to first transistors in the first bitcell. The device may have a buried wordline coupled to second transistors in the second bitcell. The device may have a frontside ground line coupled to the first transistors and the second transistors.

Described herein are various implementations of a device having an array of bitcells with first bitcells and second bitcells. The first bitcells may be disposed in a first portion of the array, and the second bitcells may be disposed in a second portion of the array that is different than the first portion of the array. The device may have a plurality of wordlines including a frontside wordline and a buried wordline formed below the frontside wordline. The frontside wordline may couple a wordline driver to the first bitcells, and the buried wordline may couple the wordline driver to the second bitcells. Also, the second bitcells in the second portion of the array may be closer to the wordline driver than the first bitcells in the first portion of the bitcell array.

It should also be understood that, although the terms first, second, etc. may be used herein to describe various elements, these elements should not be limited by these terms. These terms are only used to distinguish one element from another. For example, a first element could be termed a second element, and, similarly, a second element could be termed a first element. The first element and the second element are both elements, respectively, but they are not to be considered the same element.

The terminology used in the description of the disclosure provided herein is for the purpose of describing particular implementations and is not intended to limit the disclosure provided herein. As used in the description of the disclosure provided herein and appended claims, the singular forms “a,” “an,” and “the” are intended to include the plural forms as well, unless the context clearly indicates otherwise. The term “and/or” as used herein refers to and encompasses any and all possible combinations of one or more of the associated listed items. Also, the terms “includes,” “including,” “comprises,” and/or “comprising,” when used in this specification, may specify a presence of stated features, integers, steps, operations, elements, and/or components, but do not preclude presence or addition of one or more other various features, integers, steps, operations, elements, components and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context. The terms “up” and “down”; “upper” and “lower”; “upwardly” and “downwardly”; “below” and “above”; and other similar terms indicating relative positions above or below a given point or element may be used in connection with some implementations of various technologies described herein.

While the foregoing is directed to implementations of various related techniques described herein, other and further implementations may be devised in accordance with the disclosure herein, which may be determined by the claims that follow.

Although the subject matter has been described herein in language specific to structural features and/or methodological acts, it should be understood that the subject matter defined in the appended claims is not necessarily limited to the specific features or acts described above. Rather, specific features and acts described above are disclosed as example forms of implementing the claims.

What is claimed is:

1. A device comprising:
an array of bitcells having a first bitcell disposed adjacent to a second bitcell;
a first wordline coupled to first transistors in the first bitcell;
a second wordline coupled to second transistors in the second bitcell; and
a buried ground line coupled to the first transistors and the second transistors.

2. The device of claim 1, wherein:
the first wordline and the second wordline are formed in a frontside metal layer that is disposed above the buried ground line, and
the buried ground line is formed in a buried backside metal layer that is disposed below the first wordline and the second wordline.

3. The device of claim 1, wherein:
the first bitcell comprises a first multi-transistor bitcell with first passgates coupled to first complementary bitlines, and
the first wordline is coupled to gates of the first passgates.

4. The device of claim 3, wherein:
the second bitcell comprises a second multi-transistor bitcell with second passgates coupled to second complementary bitlines, and
the second wordline is coupled to gates of the second passgates.

5. The device of claim 4, wherein one or more precharge lines are used to precharge at least one of the first complementary bitlines and the second complementary bitlines.

6. The device of claim 1, wherein the first bitcell and the second bitcell are static random access memory (SRAM) bitcells for single-port memory applications.

7. A device comprising:
an array of bitcells having a first bitcell disposed adjacent to a second bitcell;
a frontside wordline coupled to first transistors in the first bitcell;
a buried wordline coupled to second transistors in the second bitcell; and
a frontside ground line coupled to the first transistors and the second transistors.

8. The device of claim 7, wherein:
the frontside wordline is formed in a frontside metal layer,
the buried wordline is formed in a buried backside metal layer, and
the frontside ground line is formed in the frontside metal layer.

9. The device of claim 8, wherein:
the frontside wordline and the frontside ground line are formed in the frontside metal layer that is disposed above the buried wordline, and
the buried wordline is formed in the buried backside metal layer that is disposed below the frontside wordline and the frontside ground line.

10. The device of claim 7, wherein:
the first bitcell comprises a first multi-transistor bitcell with first passgates coupled to first complementary bitlines, and
the frontside wordline is coupled to gates of the first passgates.

11. The device of claim 10, wherein:
the second bitcell comprises a second multi-transistor bitcell with second passgates coupled to second complementary bitlines, and
the buried wordline is coupled to gates of the second passgates.

12. The device of claim 11, wherein:
a frontside precharge line formed in the frontside metal layer is used to precharge at least one of the first complementary bitlines, and
a second precharge line formed in the buried backside metal layer is used to precharge at least one of the second complementary bitlines.

13. The device of claim 7, wherein the first bitcell and the second bitcell are static random access memory (SRAM) bitcells for single-port memory applications.

14. A device comprising:
an array of bitcells having first bitcells and second bitcells, wherein the first bitcells are disposed in a first portion of the array, and wherein the second bitcells are disposed in a second portion of the array that is different than the first portion of the array; and
a plurality of wordlines including a frontside wordline and a buried wordline formed below the frontside wordline, wherein the frontside wordline couples a wordline driver to the first bitcells, and wherein the buried wordline couples the wordline driver to the second bitcells, and
wherein the second bitcells in the second portion of the array are closer to the wordline driver than the first bitcells in the first portion of the bitcell array.

15. The device of claim 14, wherein the buried wordline is shorter in length than the frontside wordline.

16. The device of claim 14, wherein:
the first bitcells have first transistors,
the frontside wordline couples the wordline driver to the first transistors in the first bitcells,
the second bitcells have second transistors, and
the buried wordline couples the wordline driver to the second transistors in the second bitcells.

17. The device of claim 16, further comprising:
a frontside ground line coupled to the first transistors and the second transistors,
wherein the frontside ground line is formed in a frontside metal layer.

18. The device of claim 14, wherein:
the frontside wordline is formed in a frontside metal layer, and
the buried wordline is formed beneath the frontside wordline in a buried backside metal layer that is disposed below the frontside metal layer.

19. The device of claim 14, further comprising:
a frontside precharge line that precharges first complementary bitlines coupled to the first bitcells in the first portion of the array, and
a buried precharge line that precharges second complementary bitlines coupled to the second bitcells in the second portion of the array,
wherein the buried precharge line is shorter in length than the frontside precharge line.

20. The device of claim 14, wherein the first bitcell and the second bitcell are static random access memory (SRAM) bitcells for single-port memory applications.
